(19) United States
(12) Patent Application Publication
(10) Pub. No.: US 2010/0108496 A1
(43) Pub. Date: May 6, 2010

(54) SPUTTERING APPARATUS, THIN FILM FORMATION APPARATUS, AND MAGNETIC RECORDING MEDIUM MANUFACTURING METHOD

(75) Inventor: EINSTEIN NOEL ABARRA, HACHIOJI-SHI (JP)

Correspondence Address: BUCHANAN, INGERSOLL & ROONEY PC, POST OFFICE BOX 1404, ALEXANDRIA, VA, 22313-1404, US

(73) Assignee: CANON ANELVA CORPORATION, KAWASAKI-SHI (JP)

(21) Appl. No.: 12/573,443

(22) Filed: Oct. 5, 2009

(30) Foreign Application Priority Data
Oct. 31, 2008 (JP) 2008-282383

(51) Int. Cl. C23C 14/34

(52) U.S. Cl. 204/192.15; 204/298.09

(57) ABSTRACT

A sputtering apparatus includes a first target accommodating unit to accommodate a first target for film formation on a substrate; a first heater, arranged to surround the first target, for heating the substrate; and a second target accommodating unit arranged to surround the first heater to accommodate a second target for film formation on the substrate.

### BACKGROUND OF THE INVENTION

1. Field of the Invention

The present invention relates to a sputtering apparatus, thin film formation apparatus, and magnetic recording medium manufacturing method.

2. Description of the Related Art

Recently, magnetic recording media are being extensively researched and developed as means for recording enormous amount of information. Presently, a recording method called “perpendicular recording method” that records signals by pointing magnetization vectors in the direction perpendicular to the in-plane direction of a recording layer is being widely used.

In the magnetic recording media, a Co—Cr—Pt-based alloy is mainly used as a recording layer.

A recording layer (magnetic recording film) of the magnetic recording medium is required to have high magnetic anisotropy for thermal stability. Also, a material having high magnetic anisotropy is expected to be used in thermally assisted magnetic recording that facilitates recording nanometer-sized bits by local laser heating, or as a bit-patterned medium in which patterns are regularly arranged. Examples of promising high anisotropy material are alloys of Co and Fe such as CoPt, FePt, and CoFePt.

To obtain high magnetic anisotropy of a magnetic recording film, the substrate must be raised to and controlled at a predetermined temperature. For example, a thin-film stack manufacturing apparatus disclosed in Japanese Patent Laid-Open No. 2008-176847 includes a plurality of connected chambers, and a heating means for heating a film formation substrate. The film formation substrate is sequentially transferred into the chambers, and a plurality of thin films are stacked on the film formation substrate by using sputtering. A plurality of film formation substrates are simultaneously accommodated in the respective chambers. While a thin film is formed on one film formation substrate, the heating means heats another film formation substrate waiting for film formation.

Unfortunately, the thin-film stack manufacturing apparatus disclosed in Japanese Patent Laid-Open No. 2008-176847 has the problem that no uniform temperature control can be performed while a film is being formed or sputtered on a substrate. The thin-film stack manufacturing apparatus disclosed in Japanese Patent Laid-Open No. 2008-176847 also has the problem that the size of each chamber is large because a target as a film formation material and a first heater unit functioning as the heating means are arranged in parallel.

### SUMMARY OF THE INVENTION

The present invention provides a magnetic recording medium manufacturing technique capable of performing uniform temperature control on the substrate surface.

According to one aspect of the present invention, there is provided a sputtering apparatus comprising:

a first target accommodating unit to accommodate a first target for film formation on a substrate;

a first heater, arranged to surround the first target, for heating the substrate; and

a second target accommodating unit arranged to surround the first heater to accommodate a second target for film formation on the substrate.

According to another aspect of the present invention, there is provided a thin film forming apparatus comprising the sputtering apparatus.

According to still another aspect of the present invention, there is provided a magnetic recording medium manufacturing method comprising the steps of:

heating a substrate to a predetermined temperature using the sputtering apparatus; and

performing film formation on the substrate heated in the step of heating by using the sputtering apparatus.

According to the present invention, there can be provided a magnetic recording medium manufacturing technique capable of performing uniform temperature control on the substrate surface.

Further features of the present invention will become apparent from the following description of exemplary embodiments with reference to the attached drawings.

### BRIEF DESCRIPTION OF THE DRAWINGS

FIG. 1 is an exemplary longitudinal sectional view showing an example of a magnetic recording medium manufactured by a magnetic recording medium manufacturing method according to an embodiment of the present invention;

FIG. 2 is a schematic view showing an example of a thin film formation apparatus (magnetic recording medium manufacturing apparatus) according to the embodiment of the present invention;

FIG. 3 is a schematic view for explaining chambers 209, 210, and 211 of the magnetic recording medium manufacturing apparatus according to the embodiment of the present invention;

FIG. 4 is a side sectional view for explaining the chamber 210 of the magnetic recording medium manufacturing apparatus according to the embodiment of the present invention; and

FIG. 5 is a flowchart for explaining the sequence of the magnetic recording medium manufacturing method according to the embodiment of the present invention.

### DESCRIPTION OF THE EMBODIMENTS

Preferred embodiments of the present invention will exemplarily be explained in detail below with reference to the accompanying drawings. Note that constituent elements described in the embodiments are merely examples, and the technical scope of the present invention is determined by the scope of the appended claims and is not limited by the following individual embodiments.

First, a magnetic recording medium as an example of a thin-film stack manufactured by a magnetic recording medium manufacturing apparatus and magnetic recording medium manufacturing method according to an embodiment of the present invention will be explained. Note that in this specification, the term “magnetic recording medium” is not limited to an optical disk such as a hard disk or floppy (registered trademark) disk using only magnetism when recording and reading information. For example, a “magnetic recording medium” includes a magnetooptical recording medium such as an MO (Magneto Optical) disk using both magnetism and light, or a thermally assisted recording medium using both magnetism and heat.

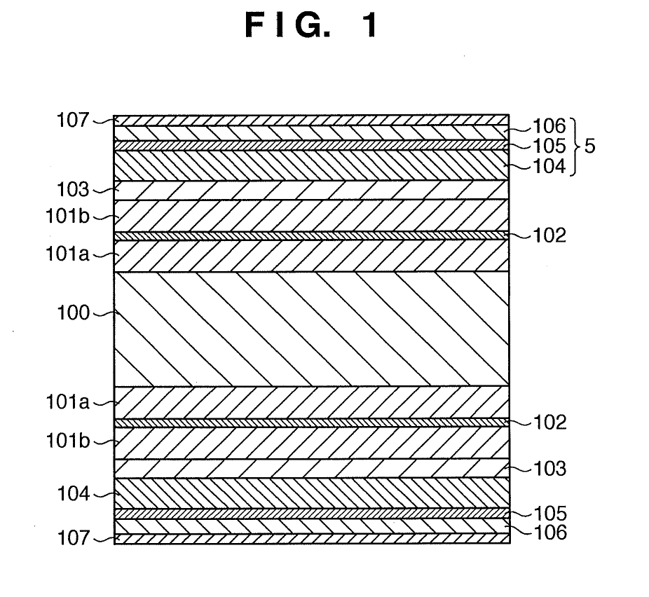

FIG. 1 is an exemplary longitudinal sectional view showing an example of a magnetic recording medium (thin film stack) manufactured by the magnetic recording medium manufacturing apparatus and magnetic recording medium manufacturing method according to the embodiment of the present invention. In this embodiment, an ECC (Exchange-Coupled Composite) medium obtained by improving a perpendicular recording medium will be explained as an example of the magnetic recording medium. However, the spirit and scope of the present invention are not limited to this example. For example, the magnetic recording medium may also be a general perpendicular recording medium, longitudinal recording medium, bit-patterned medium, or thermally assisted recording medium.

As shown in FIG. 1, the magnetic recording medium includes a substrate 100, and a first soft magnetic layer 101a, spacer layer 102, second soft magnetic layer 101b, seed layer 103, magnetic layer 104, exchange coupling control layer 105, third soft magnetic layer 106, and protective layer 107 sequentially stacked on one or both of the two surfaces of the substrate 100.

As the material of the substrate 100, it is possible to use a nonmagnetic material generally used as a magnetic recording medium substrate. Examples are glass, an Al alloy having an NiP plating film, ceramics, a flexible resin, and Si. In this embodiment, the substrate 100 is a disk-like member having a central hole. However, the present invention is not limited to this, and a rectangular member or the like may also be used.

The first soft magnetic layer 101a formed on the substrate 100 is a layer preferably formed to improve the recording/reproduction characteristics by controlling a magnetic flux from a magnetic head for use in magnetic recording. However, the first soft magnetic layer 101a may also be omitted. As the constituent material of the first soft magnetic layer 101a, it is possible to use, for example, CoZrNb, CoZrTa, or FeCoBCr.

As the material of the spacer layer 102, it is possible to use, for example, Ru or Cr. The second soft magnetic layer 101b formed on the spacer layer 102 is identical to the first soft magnetic layer 101a. The first soft magnetic layer 101a, spacer layer 102, and second soft magnetic layer 101b form a soft underlayer.

The seed layer 103 formed on the soft underlayer is a layer preferably formed immediately below the magnetic layer 104 in order to suitably control the crystal orientation, crystal grain size, grain size distribution, and grain boundary segregation of the magnetic layer 104. As the material of the seed layer 103, it is possible to use, for example, MgO, Cr, Ru, Pt, or Pd.

A magnetic recording layer 5 includes the magnetic layer 104 having a large Ku value, the exchange coupling control layer 105, and the third soft magnetic layer 106 having a small Ku value.

The magnetic layer 104 formed on the seed layer 103 and having a large Ku value affects the overall Ku value of the magnetic recording layer 5, so a material having a maximum possible Ku value is preferably used. As the material of the magnetic layer 104 which exhibits the above characteristic, it is possible to use a material having an easy magnetization axis perpendicular to the substrate surface, and having a structure in which ferromagnetic grains are isolated by the nonmagnetic grain boundary component of an oxide. For example, it is possible to use a material obtained by adding an oxide to a ferromagnetic material containing at least CoPt. Examples are CoPtCr—SiO₂ and CoPt—SiO₂. It is also possible to use Co₅₀Pt₅₀, Fe₅₀Pt₅₀, or Co_{50-y}Fe_{y}Pt₅₀.

The exchange coupling control layer 105 formed on the magnetic layer 104 contains a crystalline metal or alloy, or an oxide. As the material of the crystalline metal or alloy, it is possible to use, for example, Pt, Pd, or an alloy of Pt or Pd. As the crystalline alloy, it is also possible to use, for example, an alloy of an element selected from Co, Ni, and Fe and a nonmagnetic metal. A material with low magnetization such as a CoCrB alloy may also be employed.

The strength of the exchange coupling force between the magnetic layer 104 and third soft magnetic layer 106 can most simply be controlled by changing the film thickness or composition of the exchange coupling control layer 105. The film thickness of the exchange coupling control layer 105 is desirably, for example, 0.5 to 2.0 nm.

The third soft magnetic layer 106 formed on the exchange coupling control layer 105 mainly functions to reduce the magnetization reversing magnetic field, so a material having a minimum possible Ku value is preferably used. As the material of the third soft magnetic layer 106, it is possible to use, for example, Co, NiFe, CoNiFe, or CoCrPtB.

The protective layer 107 formed on the third soft magnetic layer 106 is formed to prevent corrosion and damage caused by the contact between a head and the medium surface. As the protective layer 107, it is possible to use, for example, a film containing a single component such as C, SiO₂, or ZrO₂, or a film obtained by adding an additive element to C, SiO₂, or ZrO₂ as a main component.

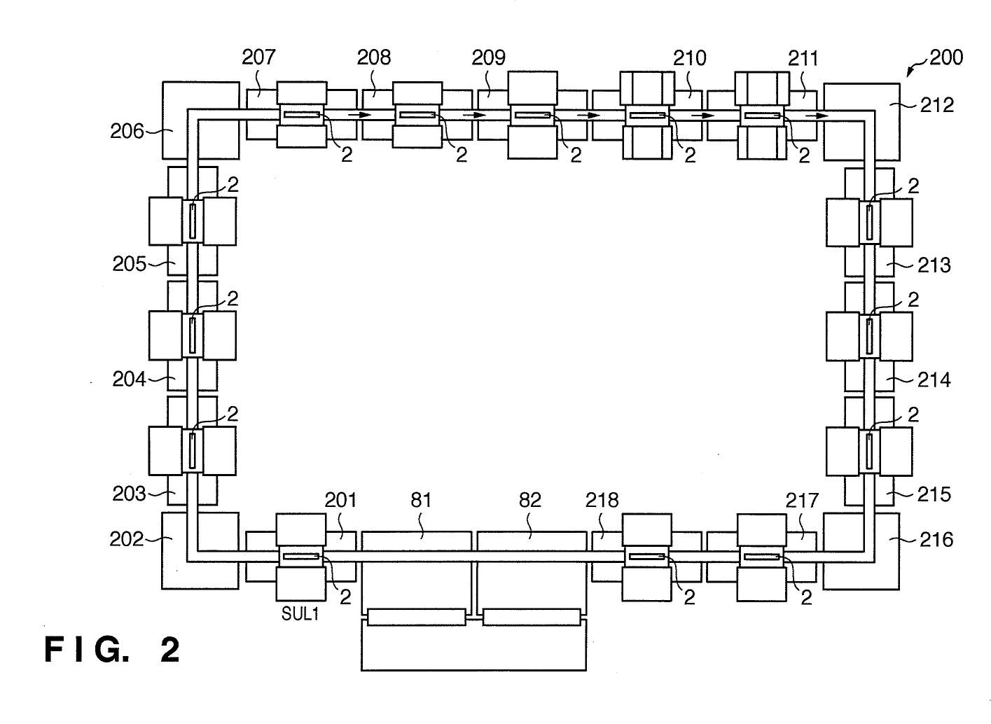

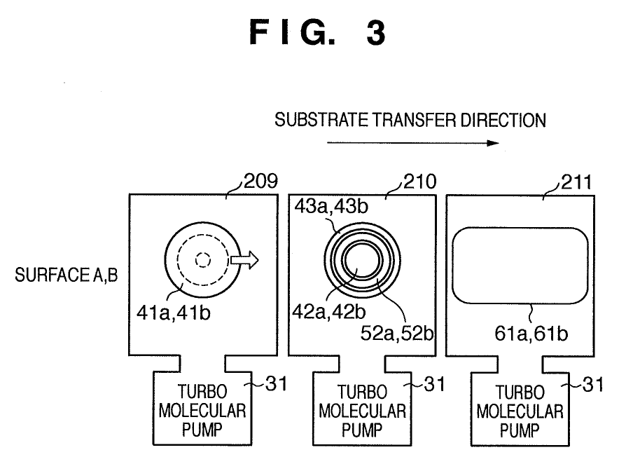

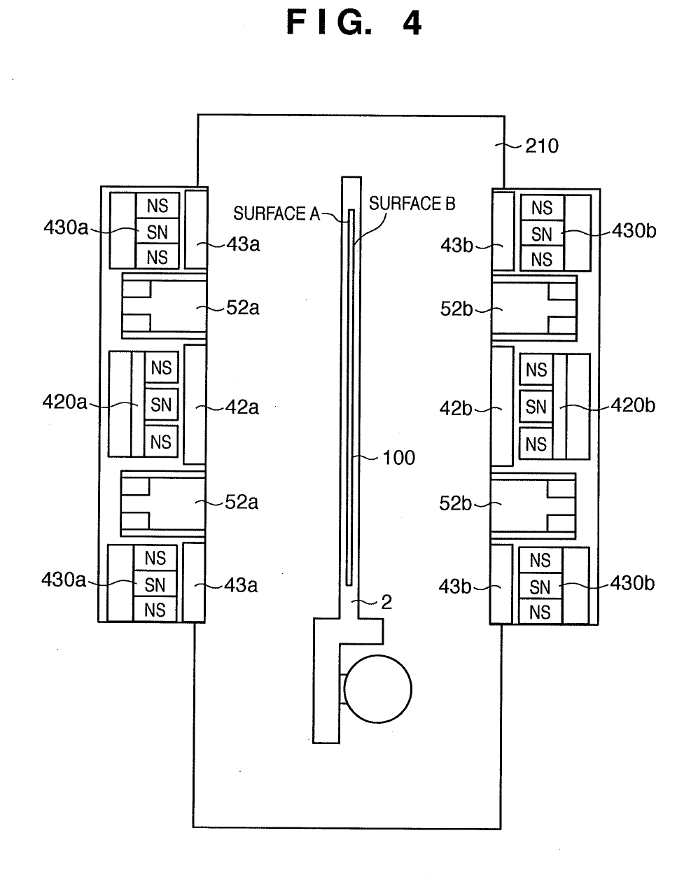

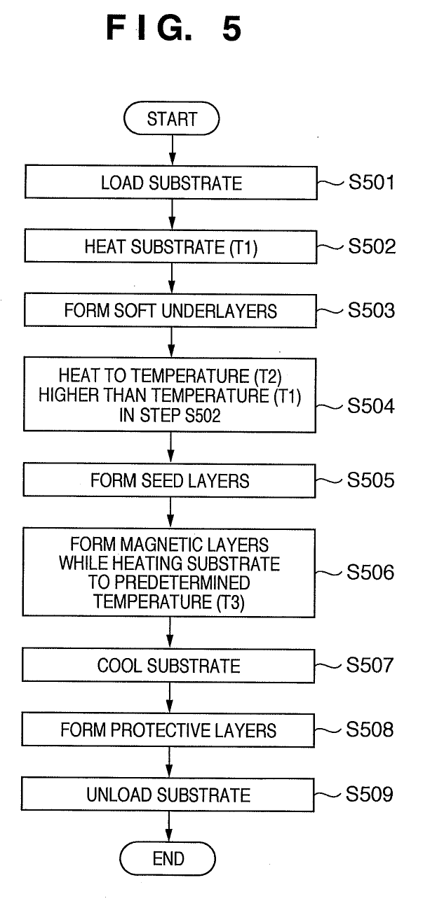

A thin film formation apparatus (to be also referred to as a “magnetic recording medium manufacturing apparatus” hereinafter) used in the magnetic recording medium manufacturing method according to the embodiment of the present invention will be explained below. FIG. 2 is an exemplary view showing an example of the magnetic recording medium manufacturing apparatus according to the embodiment of the present invention. FIG. 3 is an exemplary view for explaining chambers 209, 210, and 211 of the magnetic recording medium manufacturing apparatus. FIG. 4 is an exemplary side sectional view for explaining the chamber 210 of the magnetic recording medium manufacturing apparatus. FIG. 5 is a flowchart for explaining the sequence of the magnetic recording medium manufacturing method.

In the magnetic recording medium manufacturing apparatus as shown in FIG. 2, a load lock chamber 81 for loading the substrate 100 (FIG. 1) on a carrier 2, an unload lock chamber 82 for unloading the substrate 100 from the carrier 2, and a plurality of chambers 201, 202, 203, 204, 205, 206, 207, 208, 209, 210, 211, 212, 213, 214, 215, 216, 217, and 218 are arranged along the contours of a rectangle. Also, a transfer path is formed along the load lock chamber 81, chambers 201 to 218, and unload lock chamber 82. The transfer path has a plurality of carriers 2 capable of carrying the substrate 100. In each chamber, a processing time (tact time) required for the processing of the substrate 100 is predetermined. When this processing time (tact time) has elapsed, the carriers 2 are sequentially transferred to the next chambers.

For the magnetic recording medium manufacturing apparatus to process about 1,000 substrates per hour, the tact time in one chamber is about 5 sec or less, desirably, about 3.6 sec or less.

Each of the load lock chamber 81, unload lock chamber 82, and chambers 201, 202, 203, 204, 205, 206, 207, 208, 209, 210, 211, 212, 213, 214, 215, 216, 217, and 218 is a vacuum chamber that can be evacuated by a dedicated or shared evacuating system. Gate valves (not shown) are formed in the boundary portions between the load lock chamber 81, unload lock chamber 82, and chambers 201, 202, 203, 204, 205, 206, 207, 208, 209, 210, 211, 212, 213, 214, 215, 216, 217, and 218.

More specifically, the chamber 201 of the magnetic recording medium manufacturing apparatus forms the first soft magnetic layer 101a on the substrate 100. The direction change chamber 202 changes the transfer direction of the carrier 2. The chamber 203 forms the spacer layer 102 on the first soft magnetic layer 101a. The chamber 204 forms the second soft magnetic layer 101b on the spacer layer 102. The chamber 205 forms the seed layer 103 on the second soft magnetic layer 101b. The direction change chamber 206 changes the transfer direction of the carrier 2. The magnetic recording medium manufacturing apparatus also includes the chamber 207 (a first heating chamber) and the chamber 208 (a second heating chamber) as preheating chambers for preheating the substrate 100. The chamber 209 can also form the seed layer 103.

The chambers 210 can function as sputtering apparatus for forming the magnetic layer 104 on the seed layer 103. The cooling chamber 211 cools the substrate 100 on which the magnetic layer 104 is formed. The direction change chamber 212 changes the direction of the carrier 2. The cooling chamber 213 further cools the substrate 100. The chamber 214 forms the exchange coupling control layer 105 on the magnetic layer 104. The chamber 215 forms the third soft magnetic layer 106 on the exchange coupling control layer 105. The direction change chamber 216 changes the direction of the carrier 2. The chambers 217 and 218 form the protective layer 107.

FIG. 3 is a view for explaining details of the chamber 209 for forming the seed layer 103, the chambers 210 (sputtering apparatuses) for forming the magnetic layer 104, and the cooling chamber 211 for cooling the substrate in the magnetic recording medium manufacturing apparatus shown in FIG. 2. Arrows indicate the substrate transfer direction.

Referring to FIG. 3, the front surface (first surface) of the substrate 100 is surface A, and the rear surface (second surface) of the substrate 100, which is opposite to (faces) surface A, is surface B. In the arrangement shown in FIG. 3, the substrate 100 is clamped at the outer edges of surfaces A and B. Referring to FIG. 3, “a” attached to each reference numeral indicates the arrangement on the side of surface A, and “b” indicates that on the side of surface B.

In the chamber 209 for forming the seed layer 103, targets 41a and 41b are installed facing each other. This makes it possible to form the seed layers 103 on the two surfaces of the substrate 100. As the target material for forming the seed layers 103, it is possible to use, e.g., Cr, MgO, Pt or Pd. Note that a turbo molecular pump (to be referred to as a “TMP” hereinafter) 31 for evacuating a chamber is connected to each of the chambers 209, 210, and 211.

Next, the chamber 210 for forming the magnetic layer 104 will be explained in detail below as the feature of the present invention.

The chamber 210 functions as a sputtering apparatus and forms the magnetic layers 104 on the substrate by sputtering target materials set in the chamber 210. The chamber 210 has a first target accommodating unit for accommodating a first target 42a for film formation on the substrate, a heating means 52a (first heating means) that is formed to surround the periphery of the first target and heats the substrate, and a second target accommodating unit that is formed to surround the periphery of the heating means 52a (first heating means) and accommodates a second target 43a for film formation on the substrate.

The chamber 210 further includes a third target accommodating unit, second heating means 52b, and fourth target accommodating unit. The third target accommodating unit is arranged to face the first target accommodating unit and accommodates a third target 42b for film formation on the substrate. The second heating means 52b is arranged to face the heating means 52a (first heating means) and surround the third target 42b, and heats the substrate. The fourth target accommodating unit is arranged to face the second target accommodating unit and surround the heating means 52b (second heating means), and accommodates a fourth target 43b for film formation on the substrate.

The substrate 100 is disposed between the round and annular target and heater assemblies such that the surfaces are parallel.

The first target 42a, the heating means 52a (first heating means), and the second target 43a are concentrically arranged on the side of the first surface (surface A) of the substrate. The first target 42a is formed in a disk-like shape. The heating means 52a is concentric with the first target 42a and has an annular shape. The second target 43a is concentric with the first target. The heating means 52a concentrically surrounds the target 42a.

The third target 42b, the heating means 52b (second heating means), and the fourth target 43b are concentrically arranged on the side of the second surface (surface B) located on the side (opposing side) opposite to the first surface (surface A). The third target 42b is formed in a disk-like shape. The heating means 52b is concentric with the third target 42b and has an annular shape. The fourth target 43b is concentric with the third target and is annular in shape so as to surround the heating means 52b. The heating means 52a (first heating means) and the heating means 52b (second heating means) are arranged at positions interposed by the substrate to allow simultaneous heating the substrate from the two surfaces (first and second surfaces). This makes it possible to perform uniform temperature control and or maintain a high temperature on the substrate surfaces within the limited processing time in order to increase the throughput.

The annular heating means 52a is interposed between the first target 42a and the second target 43a to obtain a uniform film on the substrate. Their positions roughly correspond to the erosion patterns of a round target for achieving good uniformity. For example, as disclosed in the sputtering apparatus in FIGS. 7 and 8 of Japanese Patent Laid-Open No. 11-80948, as is known well, the erosion at the central portion and near the end portion of the target becomes shallow, while the erosion between the central portion and the end portion becomes deep. This undesirably results in the nonuniform film thickness of a film formed on the substrate. According to the structure of the present invention shown in FIG. 3, this problem can also be solved.

Note that as the “heating means” herein mentioned, it is possible to use, for example, a heater, block heater, or lamp heater.

The above-mentioned magnetic layer material can be used as the material of the first target 42a, third target 42b, second target 43a, and fourth target 43b. For example, it is possible to use a material obtained by adding an oxide to a ferromagnetic material containing at least CoPt. Examples are CoPtCr—SiO₂ and CoPt—SiO₂. It is also possible to use Co₅₀Pt₅₀, Fe₅₀Pt₅₀, or Co_{50-y}Fe_{y}Pt₅₀ as another target material.

FIG. 4 is a schematic side sectional view showing the chamber 210 in the substrate transfer direction (the substrate transfer direction is perpendicular to the drawing surface). That surface of the first target 42a which faces the substrate and that surface of the third target 42b which faces the substrate are arranged in positions almost symmetrical with respect to the substrate. Similarly, that surface of the heating means 52a which faces the substrate and that surface of the heating means 52b which faces the substrate are arranged in positions almost symmetrical with respect to the substrate. Further, that surface of the second target 43a which faces the substrate and that surface of the fourth target 43b which faces the substrate are arranged in positions almost symmetrical with respect to the substrate.

Note that magnet units 420a and 420b are installed at the back of the first target 42a, and the third target 42b, and magnet units 430a and 430b are installed at the back of the second target 43a, and the fourth target 43b.

The magnet units 420a and 420b also provide a first means to generate an electric field at a predetermined voltage on the targets 42a and 42b, respectively. The magnet units 430a and 430b provide a second means to generate an electric field at a predetermined voltage on the targets 43a and 43b. The electric fields promote plasma formation in the presence of a working gas in the chamber that effects sputtering.

Though FIG. 4 shows the surfaces of the first target 42a, heating means 52a, and second target 43a which face the substrate are aligned and form a single plane, the surfaces need not be co-planar. Likewise, the surfaces of the third target 42b, heating means 52b, and fourth target 43b are parallel but need not be co-planar.

For the magnetic recording medium manufacturing apparatus to process about 1,000 substrates per hour, the tact time in one chamber must be shortened to about 5 sec or less, desirably, about 3.6 sec or less as described previously. To achieve a heating process (temperature control) for heating the substrate to a desired temperature (about 400° C. to 600° C.) while the tact time is thus limited, the surfaces of the heating means 52a and 52b are preferably arranged at a distance of, for example, 50 mm or less, desirably, 30 mm or less from the substrate surface.

Referring back to FIG. 3, the cooling chamber 211 shown in FIG. 3 has cooling mechanisms 61a and 61b facing each other, in order to cool the two surfaces of the substrate on which the magnetic layers 104 are formed. The two surfaces of the substrate having the magnetic layers 104 formed by heating to the desired temperature in the chambers 210 are cooled by the cooling mechanism 61a (first cooling mechanism) and cooling mechanism 61b (second cooling mechanism) in the cooling chamber 211. The cooling process in the cooling chamber 211 can cool the substrate to a temperature optimum for later formation of the protective layers 107, for example, to about 200° C. or less.

As explained above, this embodiment can provide a sputtering apparatus and magnetic recording medium manufacturing apparatus capable of performing uniform temperature control on the substrate surfaces especially during sputtering.

Next, a magnetic recording medium manufacturing method using the magnetic recording medium manufacturing apparatus according to the embodiment of the present invention will be explained below with reference to FIGS. 1 and 5.

In step S501, a substrate is carried into the load lock chamber 81 and placed on the carrier 2 by a substrate transfer robot (not shown).

In step S502, the substrate is heated to a predetermined temperature T1 (about 100° C.) in the load lock chamber 81, thereby removing contaminants and water sticking to the substrate.

In step S503, soft underlayers are formed. More specifically, first soft magnetic layers 101a are formed in the chamber 201, spacer layers 102 (the thickness is 0.7 to 2 nm) are formed in the chamber 203, and second soft magnetic layers 101b are formed in the chamber 204.

In step S504, the substrate is sequentially transferred to the chamber 207 (first heating chamber) and chamber 208 (second heating chamber), and heated to a temperature T2 (about 400° C. to 700° C.) higher than the temperature T1 (about 100° C.) in step S502. This step is a preparation step of increasing the magnetic anisotropy of magnetic recording layers when forming magnetic layers 104 later. In the magnetic recording medium manufacturing apparatus, the processing time (tact time) in one chamber is limited in order to increase the throughput. In the chambers 210 for forming magnetic layers 104, it is difficult to heat the substrate to a temperature required to increase the magnetic anisotropy of magnetic layers 104 within the limited time. Therefore, the magnetic recording medium manufacturing apparatus includes the chamber 207 (first heating chamber) and chamber 208 (second heating chamber) for preheating (preliminary heating). In the magnetic recording medium manufacturing apparatus, the chamber 207 (first heating chamber) and chamber 208 (second heating chamber) function as preliminary heating means.

Since the substrate temperature decreases before the substrate is completely transferred to the chamber 210 for forming magnetic layers 104, the substrate must be heated (preliminarily heated) in the chamber 207 (first heating chamber) and chamber 208 (second heating chamber) to a temperature equal to or higher than the temperature required to increase the magnetic anisotropy in the chamber 210. If the substrate made of glass is overheated, however, it may plastically deform and fall from the carrier 2. In the chamber 207 (first heating chamber) and chamber 208 (second heating chamber), therefore, the glass substrate is preferably heated to a temperature below where plastic deformation occurs. For some glass substrates this may be up to, for example, 600° C.

In step S505, seed layers 103 are formed to suitably control the crystal characteristics of magnetic layers 104. Note that the seed layers 103 may also be formed in the chamber 205 before the heating step in step S504.

In step S506, the substrate is transferred to the chambers 210 for forming magnetic layers 104, and magnetic layers 104 are formed while the substrate is heated to a predetermined temperature T3 (about 400° C. to 600° C.). In this step, the magnetic layers 104 are formed while the substrate is uniformly heated in the chamber 210 as described previously.

In step S507, the substrates are sequentially transferred to the cooling chambers 211 and 213 and cooled to a temperature optimum for the formation of protective layers 107. When using carbon as the material of the protective layers 107, the substrate must be cooled to, for example, about 200° C. or less.

In step S508, the substrate is transferred to the chambers 217 and 218 for protective layers 107 deposition which may be formed by CVD.

Note that ultra-thin exchange coupling control layers 105 may also be formed between the magnetic layers 104 and protective layers 107 in the chamber 214. Note also that third soft magnetic layers 106 may also be formed in the chamber 215 after the substrate is cooled and before the protective layers 107 are formed.

Finally, in step S509, the substrate is unloaded as it is removed from the carrier 2 in the unload lock chamber 82.

As explained above, this embodiment can provide a magnetic recording medium manufacturing method capable of performing uniform temperature control on substrate surfaces.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2008-282383 filed on Oct. 31, 2008, which is hereby incorporated by reference herein in its entirety.

1. A sputtering apparatus comprising:
a first target accommodating unit to accommodate a first target for film formation on a substrate;
a first heater, arranged to surround the first target, for heating the substrate; and
a second target accommodating unit arranged to surround said first heater to accommodate a second target for film formation on the substrate.

2. The apparatus according to claim 1, wherein said first target accommodating unit, said first heater, and said second target accommodating unit are arranged concentrically.

3. The apparatus according to claim 1, further comprising:
a third target accommodating unit arranged to face said first target accommodating unit to accommodate a third target for film formation on the substrate;
a second heater, arranged to face said first heater and surround said third target, for heating the substrate; and
a fourth target accommodating unit arranged to face said second target accommodating unit and surround said second heater to accommodate a fourth target for film formation on the substrate.

4. The apparatus according to claim 3, wherein said third target accommodating unit, said second heater, and said fourth target accommodating unit are arranged concentrically.

5. The apparatus according to claim 1, wherein said first heater heats a first surface of the substrate, and the first target accommodated in said first target accommodating unit and the second target accommodated in said second target accommodating unit are used for film formation on the first surface of the substrate.

6. The apparatus according to claim 3, wherein said second heater heats the second surface of the substrate which opposes the first surface, and the third target accommodated in said third target accommodating unit and the fourth target accommodated in said fourth target accommodating unit are used for film formation on the second surface of the substrate.

7. A thin film forming apparatus comprising a sputtering apparatus defined in claim 1.

8. A magnetic recording medium manufacturing method comprising the steps of:
heating a substrate to a predetermined temperature using a sputtering apparatus defined in claim 1; and
performing film formation on the substrate heated in the step of heating by using the sputtering apparatus defined in claim 1.
